(19) United States
(12) Patent Application Publication
(10) Pub. No.: US 2015/0332830 A1
(43) Pub. Date: Nov. 19, 2015

(54) APPARATUS FOR THERMAL SHIELDING OF A SUPERCONDUCTING MAGNET

(71) Applicant: General Electric Company, Schenectady, NY (US)

(72) Inventors: Longzhi Jiang, Florence, SC (US); Gregory Alan Lehmann, Brookfield, WI (US); Neil Clarke, Oxford (GB)

(21) Appl. No.: 14/809,968

(22) Filed: Jul. 27, 2015

Related U.S. Application Data
(63) Continuation of application No. 10/908,752, filed on May 25, 2005.

(51) Int. Cl. H01F 6/04; F25D 19/00; G01R 33/3815; F25D 3/00

(52) U.S. Cl. CPC H01F 6/04; F25D 3/00; F25D 19/006; G01R 33/3815

(57) ABSTRACT

A thermal shield for a superconducting magnet includes a shield body having an annular shape. The shield body includes a material having a thermal conductivity greater than about 1000 W/m·K at about 70K.

### BACKGROUND OF THE INVENTION

The present invention relates to a thermal shield and, more particularly, to a thermal shield for use with a superconducting magnet of, for example, a magnetic resonance imaging (MRI) system.

MRI systems are commonly used in medical imaging applications since MRI scans produce detailed images of soft tissues. MRI systems produce images by excitation of selected dipoles within a subject and receiving magnetic resonance signals emanating from the dipoles. In order to produce the excitation of selected dipoles within the subject, a powerful and uniform magnetic field is required. The powerful and uniform magnetic field may be produced by superconducting magnet coils.

Superconducting magnetic coils operate under cryogenic temperatures and therefore require robust cooling systems. The cooling systems typically require a cryogen or refrigerant, for example, liquid helium, in order to achieve cryogenic temperatures. However, cryogens are not abundant and often add significant cost to a cryostat portion of an MRI system. Thus, it is desirable to thermally isolate the superconducting magnet coils to the greatest extent possible to minimize cooling requirements.

In order to thermally isolate the superconducting magnet coils, thermal shields have been disposed around the superconducting magnet coils. Aluminum alloys have typically been employed for the thermal shields. Aluminum is considered advantageous for having properties including a low density and a light weight, while maintaining good strength and thermal conductivity characteristics. However, a disadvantage of aluminum is that aluminum has a high electrical conductivity. High electrical conductivity creates large mechanical stresses on the thermal shields when the magnet becomes normal or quenched. Additionally, aluminum thermal shields suffer from field instability that may reduce a quality of images obtained by the MRI system.

Two types of field instability, gradient and vibration induced field instability affect aluminum thermal shields by producing eddy currents in the thermal shield that reduce image quality. Vibration induced field instability is caused by vibration from a cooling engine (coldhead), environmental excitation and gradient pulse. Such vibration produces eddy currents that reduce image quality and are complex and costly to avoid. Gradient field instability is a result of magnetic fields generated during gradient pulse that may cause image artifacts.

Thus, it is desirable to design a thermal shield that improves upon existing art.

### BRIEF DESCRIPTION OF THE INVENTION

Exemplary embodiments of the invention include a thermal shield for a superconducting magnet. The thermal shield for a superconducting magnet includes a shield body having an annular shape. The shield body includes a material having a thermal conductivity greater than about 1000 W/m·K at about 70K.

Further exemplary embodiments of the invention include a shielding system for shielding and cooling a superconducting magnet coil via a cryogen. The shielding system includes a cryogen vessel, a thermal shield, and a vacuum vessel. The cryogen vessel contains the cryogen and is disposed proximate to the superconducting magnet coil to enclose the superconducting magnet coil. The thermal shield includes a shield body comprising a material having a thermal conductivity greater than about 1000 W/m·K at about 70K. The thermal shield is disposed proximate to the cryogen vessel to enclose the cryogen vessel. The vacuum vessel is disposed proximate to the thermal shield to enclose the thermal shield.

Still further exemplary embodiments of the invention include a thermal shield for a superconducting magnet. The thermal shield includes a shield body having an annular shape and a cladding. The cladding includes a material having a thermal conductivity greater than about 1000 W/m·K at about 70K. The cladding is disposed at a surface of the shield body.

The above, and other objects, features and advantages of the present invention will become apparent from the following description read in conjunction with the accompanying drawings, in which like reference numerals designate the same elements.

### BRIEF DESCRIPTION OF THE DRAWINGS

Referring now to the drawings wherein like elements are numbered alike in the several FIGURES:

FIG. 1 shows a sectional view of a shielding system according to an exemplary embodiment;

FIG. 2 shows a sectional view of an composite thermal shield according to an exemplary embodiment; and

FIG. 3 shows an expanded view of a joint section of the composite thermal shield of FIG. 2.

### DETAILED DESCRIPTION OF THE INVENTION

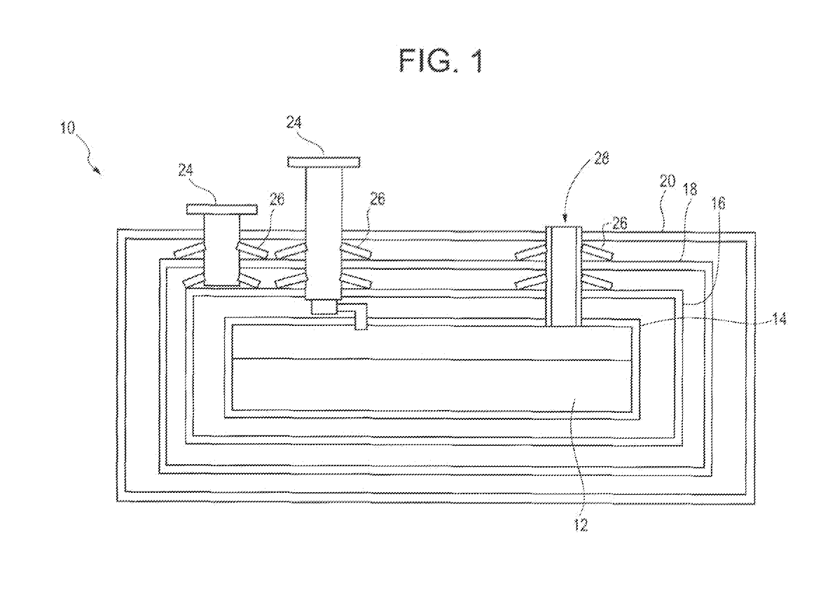

FIG. 1 shows a sectional view of a shielding system according to an exemplary embodiment. A shielding system 10 for a superconducting magnet coil 12 includes a helium vessel 14 (or cryogen vessel), a low temperature thermal shield 16, a high temperature thermal shield 18 and a vacuum vessel 20. The shielding system 10 extends around an imaging space (not shown) to form an annular shape around a circumference of the imaging space. Each of the superconducting magnet coil 12, the helium vessel 14, the low temperature thermal shield 16, the high temperature thermal shield 18 and the vacuum vessel 20 similarly extend around the circumference of the imaging space in an annular shape.

The superconducting magnet coil 12 may be any suitable superconducting coil known in the art. The helium vessel 14 is disposed proximate to the superconducting magnet coil 12 to enclose the superconducting magnet coil 12. The helium vessel 14 is filled with a cryogenic coolant, for example, liquid helium. The cryogenic coolant provides cooling to the superconducting magnet coil 12 to allow the superconducting magnet coil 12 to achieve superconductivity at cryogenic temperatures. In this exemplary embodiment, the helium vessel 14 has a shape of a hollow rectangular prism extended to form an annular shape, however, any suitable shape is envisioned.

The low temperature thermal shield 16 is disposed proximate to the helium vessel 14 to enclose the helium vessel 14. The high temperature thermal shield 18 is disposed proximate to the low temperature thermal shield 16 to enclose the low temperature thermal shield 16. The low and high temperature thermal shields 16 and 18 function to thermally isolate the superconducting magnet coil 12 to reduce the cooling requirements on the cryogenic coolant. A shape of the low and high temperature thermal shields 16 and 18 is substantially similar to that of the helium vessel 14. Although FIG. 1 shows two thermal shields, it should be noted that either more or less thermal shields may be employed depending on operational requirements of the shielding system 10.

The low and high temperature thermal shields 16 and 18 are each in thermal contact with a portion of a coldhead sleeve 24. In an exemplary embodiment, the low and high temperature thermal shields 16 and 18 may each be in physical contact with the coldhead sleeve 24. Alternatively, a thermal link 26 may provide thermal contact between the low and high temperature thermal shields 16 and 18 and the coldhead sleeve 24.

The coldhead sleeve 24 provides a means for cooling the low and high temperature thermal shields 16 and 18. In an exemplary embodiment, a cooling engine (not shown) provides cooling to the low and high temperature thermal shields 16 and 18 to cool the low and high temperature thermal shields 16 and 18 to a temperature of about 45K to about 70K, which varies in response to a conductance of a thermal shield. The cooling engine may be, for example, a stirling or pulse tube type, but is not limited to any particular engine. The shielding system 10 may alternatively include a plurality of coldhead sleeves 24, as shown in FIG. 1. The coldhead sleeve 24 may include a recondenser 28 in thermal communication with the cryogenic coolant.

The vacuum vessel 20 is disposed proximate to the high temperature thermal shield 18 to enclose the high temperature thermal shield 18 and maintain interior portions of the vacuum vessel 20 substantially at a vacuum with respect to regions exterior to the vacuum vessel 20. A shape of the vacuum vessel 20 is substantially similar to that of the low and high temperature thermal shields 16 and 18 and the helium vessel 14.

In an exemplary embodiment, a penetration 28 passes through the vacuum vessel 20, the high temperature thermal shield 18, the low temperature thermal shield 16, and the helium vessel 14. The penetration 28 provides a conduit to pass wires for electrical communication with the superconducting magnet coil 12 or instrumentation to monitor a characteristic of the superconducting magnet coil 12. The penetration 28 may include thermal links 26 providing thermal communication with the low and high temperature thermal shields 16 and 18.

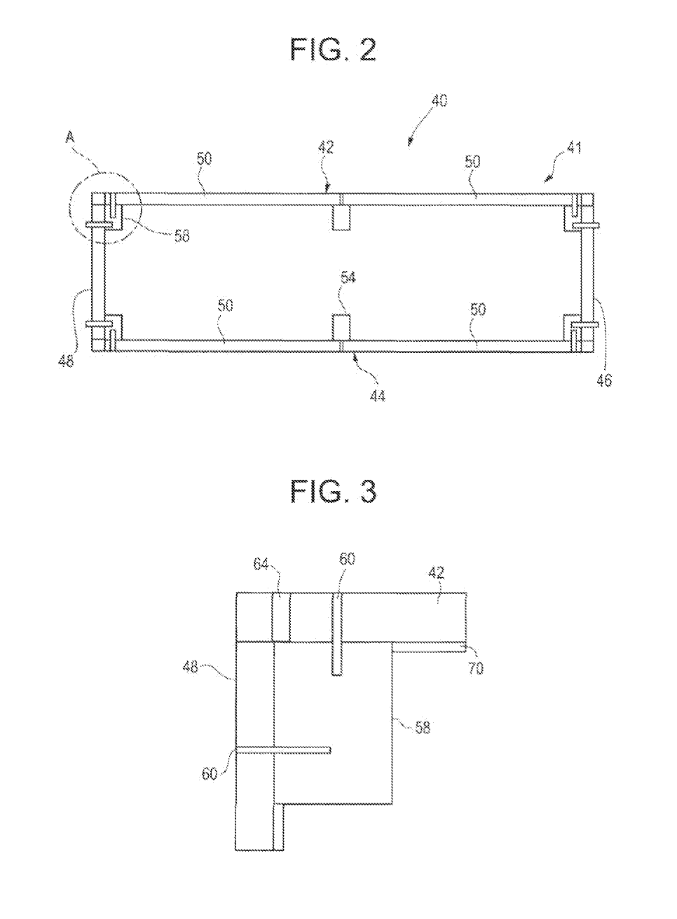

In an exemplary embodiment, the low and high temperature thermal shields 16 and 18 are each a composite thermal shield 40 (see FIG. 2). Alternatively, one of the low and high temperature thermal shields 16 and 18 may be a composite thermal shield 40, while the other is a conventional thermal shield. Additionally, if the shielding system 10 comprises a plurality of thermal shields, it should be understood that any combination of conventional thermal shields and composite thermal shields 40 may be employed.

FIG. 2 shows a sectional view of a composite thermal shield 40 according to an exemplary embodiment. The composite shield 40 according to this exemplary embodiment employs a shape of a hollow rectangular prism extended annularly around the circumference of the imaging space, but any suitable shape may be employed. The composite thermal shield 40 includes a shield body 41 having a first sidewall 42, a second sidewall, 44, a third sidewall 46, and a fourth sidewall 48. Each of the first to fourth sidewalls 42 to 48 is made of a composite material to be described in greater detail below. When viewed in a cross section, the first sidewall 42 is disposed substantially perpendicular to the third sidewall 46 and the fourth sidewall 48. End portions of the third and fourth sidewalls 46 and 48 are disposed proximate to opposite end portions of the first sidewall 42, such that the third and fourth sidewalls 46 and 48 are substantially parallel to each other and face each other. The second sidewall 44 is disposed substantially perpendicular to the third and fourth sidewalls 46 and 48. The second sidewall 44 is disposed proximate to opposite end portions of each of the third and fourth sidewalls 46 and 48, such that the second sidewall 44 is substantially parallel to the first sidewall 42 and faces the first sidewall 42. The first to fourth sidewalls 42 to 48 define a receiving space to receive, for example, the superconducting magnet coil 12, the helium vessel 14 or another thermal shield.

In an exemplary embodiment, the first and second sidewalls 42 and 44 each include sub-members 50. Although FIG. shows two sub-members 50 for each of the first and second sidewalls 42 and 44, it should be understood that additional sub-members 50 may be employed. Each sub-member 50 forms an opposite end portion of the first and second sidewalls 42 and 44. Additionally, adjacent ends of each sub-member 50 are joined by a center support ring 54. The center support ring 54 extends around an interior portion of the composite thermal shield 40 to seal a joint between each sub-member 50.

Joints between each of the first to fourth sidewalls 42 to 48 are sealed by a corner support ring 58. Each corner support ring 58 extends around an interior portion of the composite thermal shield 40 to seal the joints between each of the first to fourth sidewalls 42 to 48.

FIG. 3 shows an expanded view of a joint section “A” of the composite thermal shield 40 of FIG. 2. FIG. 3 shows the joint section “A” between the first and fourth sidewalls 42 and 48, but each other joint section is substantially identical. The first and fourth sidewalls 42 and 48 are sealed by the corner support ring 58. Screws 60 may engage the corner support ring 58 via holes in each of the first and fourth sidewalls 42 and 48. Additionally, a high thermal conductive epoxy 64 may be disposed between the first and fourth sidewalls 42 and 48 at a location of contact between the first and fourth sidewalls 42 and 48.

The composite material used to make each of the first and fourth sidewalls 42 and 48 is chosen for its low density, high thermal conductivity and low electrical conductivity relative to aluminum and aluminum alloys. For example, thermal pyrolytic graphite (TPG) and pyrolitic boron nitride (PBN) may be used. The composite material is selected to have a thermal conductivity greater than about 1000 W/m·K at about 70K. Since aluminum has a thermal conductivity of about 300 W/m·K, thickness of a thermal shield may be reduced by three times and still achieve similar thermal performance to an aluminum thermal shield. The composite material is selected to have an electrical resistivity in a range of about 3 10−6 Ωm to about 3 10−3 Ωm. Since the composite material has a high electrical resistivity as compared to a conventional thermal shield, eddy currents induced in a thermal shield having the high electrical resistivity are negligible. Thus, vibration and gradient coil induced field instability are negligible. The composite material is selected to have density less than about 2.4 g/cm3 or about 10% less than aluminum, thereby decreasing weight of the thermal shield.

A surface of the composite thermal shield 40 that faces the helium vessel 14 must have emissivity control to reduce heat radiation from the composite thermal shield 40 to the helium vessel 14. To achieve the emissivity control, high conductive aluminum tape 70 may be applied to an inner surface of the composite thermal shield 40.

As stated above, any combination of composite thermal shields 40 and conventional thermal shields may be employed. Additionally, a conventional thermal shield may be disposed in contact and enclosing a composite thermal shield 40. Alternatively, a conventional thermal shield may be clad with TPG or PBN to provide improved performance. Furthermore, a thickness of TPG or PBN cladding may be varied to optimize thermal gradient and average shield temperature reductions.

In addition, while the invention has been described with reference to exemplary embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims. Moreover, the use of the terms first, second, etc. do not denote any order or importance, but rather the terms first, second, etc. are used to distinguish one element from another. Furthermore, the use of the terms a, an, etc. do not denote a limitation of quantity, but rather denote the presence of at least one of the referenced item.

1-20. (canceled)

21. A thermal shield for a superconducting magnet, the thermal shield comprising:
a first shield body having a ring shape and sized to surround a cryogen vessel, the first shield body comprising:
a first sidewall assembly;
a second sidewall assembly; and
a plurality of mechanical joints coupling the first sidewall assembly to the second sidewall assembly; and
wherein each of the plurality of mechanical joints comprises a corner support ring disposed along a first portion of an interior surface of a respective sidewall of the first sidewall assembly and a first portion of an interior surface of a respective sidewall of the second sidewall assembly.

22. The thermal shield of claim 21 wherein the first shield body further comprises a material having a thermal conductivity greater than about 1000 W/m·K at about 70K.

23. The thermal shield of claim 21 further comprising a plurality of screws coupling the first sidewall assembly and the second sidewall assembly to a respective corner support ring.

24. The thermal shield of claim 21 wherein the first sidewall assembly comprises a first sub-member and second sub-member;
wherein a first end of the first sub-member is coupled to a first corner support ring; and
wherein a first end of the second sub-member is coupled to a second corner support ring.

25. The thermal shield of claim 24 further comprising a center support ring coupling a second end of the first sub-member to a second end of the second sub-member.

26. The thermal shield of claim 21 further comprising a second shield body having an annular shape, the second shield body sized to surround the first shield body; and
wherein the first shield body and the second shield body are positioned to form a gap therebetween.

27. The thermal shield of claim 21 further comprising an adhesive disposed at a contact location between a sidewall of the first sidewall assembly and a sidewall of the second sidewall assembly.

28. The thermal shield of claim 21 further comprising at least one of a cladding coupled to an exterior surface of the first shield body and an emissivity control tape coupled to an interior surface of first shield body.

29. The thermal shield of claim 21 wherein the first shield body comprises a material having a density less than about 2.4 g/cm³.

30. A thermal shield for a superconducting magnet, the thermal shield comprising:
a first sidewall assembly comprising a material having a thermal conductivity greater than about 1000 W/m·K at 70K;
a second sidewall assembly comprising a material having a thermal conductivity greater than about 1000 W/m·K at 70K; and
wherein the first sidewall assembly is coupled to the second sidewall assembly to form a first ring-shaped thermal shield.

31. The thermal shield of claim 30 further comprising a plurality of mechanical joints coupling the first sidewall assembly to the second sidewall assembly, wherein the plurality of mechanical joints comprise corner support rings disposed along a first portion of an interior surface of the first sidewall assembly and a first portion of an interior surface of the second sidewall assembly.

32. The thermal shield of claim 31 wherein each of the plurality of mechanical joints further comprise a plurality of screws coupling the corner support ring with the first portions of the interior surfaces of the first and second sidewall assemblies.

33. The thermal shield of claim 30 further comprising a second ring-shaped thermal shield positioned to surround the first ring-shaped thermal shield; and
wherein a gap is formed between the first and second ring-shaped thermal shields, the gap having a vacuum maintained therein.

34. The thermal shield of claim 30 further comprising an epoxy applied at a contact location between an end surface of the first sidewall assembly and an end surface of the second sidewall assembly.

35. The thermal shield of claim 30 further comprising an emissivity control tape coupled to an interior surface of at least one of the first sidewall assembly and the second sidewall assembly.

36. A shielding system for shielding and cooling a superconducting magnet coil via a cryogen, the system comprising:
a cryogen vessel;
a first ring-shaped thermal shield sized to surround the cryogen vessel, the ring-shaped thermal shield comprising:
a first sidewall assembly;
a second sidewall assembly;
a plurality of mechanical joints coupling the first sidewall assembly to the second sidewall assembly;
wherein each of the plurality of mechanical joints comprises a corner support ring disposed along a first portion of an interior surface of a respective sidewall of the first sidewall assembly and a first portion of an interior surface of a respective sidewall of the second sidewall assembly; and
wherein the first and second sidewall assemblies comprise at least one of thermal pyrolytic graphite (TPG) and pyrolytic boron nitride (PBN); and
a vacuum vessel positioned to enclose the first ring-shaped thermal shield.

37. The system of claim 36 further comprising:
a second ring-shaped thermal shield sized to surround the first ring-shaped thermal shield such that a gap is formed between the first and second ring-shaped thermal shields;
thermal links coupled between the first and second ring-shaped thermal shields and a coldhead sleeve; and
wiring extending through a penetration formed in the first and second ring-shaped thermal shields and the vacuum vessel and coupled to the superconducting magnet.

38. The system of claim 36 further comprising an epoxy disposed at a location of contact between a sidewall of the first sidewall assembly and a sidewall of the second sidewall assembly.

39. The system of claim 36 wherein each mechanical joint further comprises a plurality of screws;
wherein at least one of the plurality of screws couples the first sidewall assembly to the corner support ring; and
wherein at least one of the plurality of screws couples the second sidewall assembly to the corner support ring.

40. The system of claim 36 wherein the first ring-shaped thermal shield further comprises a cladding coupled to an exterior surface thereof and comprising a material having a thermal conductivity greater than about 1000 W/m·K at about 70K, a density less than about 2.4 g/cm³, and an electrical resistivity in a range of about 3×10⁻⁶ Ωm to about 3×10⁻³ Ωm.
